(19) United States
(12) Patent Application Publication
(10) Pub. No.: US 2025/0231266 A1
(43) Pub. Date: Jul. 17, 2025

(54) Magnetic Resonance Image Reconstruction

(71) Applicant: Siemens Healthineers AG, Forchheim (DE)

(72) Inventor: Marcel Dominik Nickel, Herzogenaurach (DE)

(73) Assignee: Siemens Healthineers AG, Forchheim (DE)

(21) Appl. No.: 19/018,004

(22) Filed: Jan. 13, 2025

(30) Foreign Application Priority Data
Jan. 15, 2024 (EP) 24151851.3

(51) Int. Cl. G01R 33/56; G06T 5/60

(52) U.S. Cl. CPC G01R 33/5608; G06T 5/60; G06T 2207/10088

(57) ABSTRACT

For MR image reconstruction, MR measurement data representing an imaged object is obtained and, for each iteration of at least two iterations, a prior MR image for the respective iteration is received, an optimized MR image is generated by optimizing a predefined first loss function, which depends on the MR measurement data and on the prior MR image, and an enhanced MR image is generated by applying a trained machine learning model, MLM, for image enhancement to the optimized MR image. The prior MR image of the respective iteration corresponds to the enhanced MR image of a preceding iteration, unless the respective iteration corresponds to an initial iteration of the at least two iterations, and the prior MR image of the initial iteration corresponds to a predefined initial image.

### CROSS REFERENCE TO RELATED APPLICATIONS

This patent application claims priority to EP PATENT APPLICATION No. 24151851.3, filed Jan. 15, 2024, which is incorporated herein by reference in its entirety.

### BACKGROUND

### Field

The present disclosure is directed to a computer implemented method for magnetic resonance (MR) image reconstruction and to a computer implemented training method for training a machine learning model (MLM) for image enhancement for use in such a computer implemented method for MR image reconstruction. The disclosure is further directed to a data processing apparatus for carrying out the computer implemented method for MR image reconstruction and/or the computer implemented training method and to a corresponding computer program product.

### Related Art

In MR imaging, image reconstruction denotes the process to generate a two-dimensional image or a three-dimensional image, typically in form of multiple two-dimensional images for multiple positions along the so-called slice direction, in position space from the MR data acquired in k-space depending on MR signals being emitted by an object to be imaged. In the disclosure, the term “image” denotes an image in position space, also denoted as image space or image domain, unless stated otherwise.

In general, k-space and the position space are related to each other via Fourier transformation.

When parallel MR imaging is pursued, MR data are received from multiple receiver coils, which receive the emitted MR signals. Furthermore, k-space subsampling techniques may be employed, where the k-space is sampled with a sampling rate that is too low to fulfil the Nyquist criterion. The latter is also denoted as undersampling or incomplete sampling. The multiple coils or the data provided by them, respectively, are denoted as coil channels. The reconstructed MR image can therefore not be obtained solely by Fourier transforming the acquired k-space data. Rather, more sophisticated reconstruction techniques need to be used. Various methods for MR image reconstruction are known, which may for example involve iterative processes and/or optimizations based on physical relations.

In the reconstruction process, application specific parameters may be considered. These parameters may origin from different physical contexts depending on the specific application. The parameters may for example be related to the motion of an object to be imaged during data acquisition, the specific underlying k-space sampling pattern, and so forth.

Furthermore, trained machine learning models MLMs for example artificial neural networks (ANNs), in particular deep convolutional neural networks (CNNs) may be used for the MR image reconstruction, for example in combination with conventional reconstruction approaches. Therein, “conventional” refers to the fact that no MLM is involved. Such methods are sometimes called deep learning (DL) reconstructions. A review of the topic is presented in the publication G. Zeng et al.: “A review on deep learning MRI reconstruction without fully sampled k-space.” BMC Med Imaging 21, 195 (2021).

U-Net, introduced in the publication of O. Ronneberger et al.: “U-Net: Convolutional Networks for Biomedical Image Segmentation” (arXiv:1505.04597v1), is a well-known CNN usable for example for image segmentation or image enhancement.

One approach to train MLMs, in particular ANNs, is supervised training. Therein, training data, for example training MR images in the present context, and corresponding ground truth data, for example a reconstructed MR image in the present context, are provided. The training data is fed to the MLM, which outputs a prediction, which is then compared to the ground truth data by evaluating a loss function. The loss function may be minimized to train the MLM.

In view of the application specific parameters mentioned above, one can for example train a dedicated MLM for each application. This, however, increases the overall training effort, in particular in terms of the total computational time required for the training of all MLMs, the required amount of training data, and so forth.

CAIPIRINHA is a parallel imaging technique using group unique k-space sampling patterns. In this way, pixel aliasing and overlap may be avoided. The points measured in k-space are shifted by applying offsets to the phase-encoding gradients. Wave-CAIPI is a variant of CAIPIRINHA operating with a 3D pattern that uses coil sensitivities along the readout direction and is described, for example, in the publication D. Polak et al.: “Wave-CAIPI for highly accelerated MP-RAGE imaging,” Magnetic resonance in medicine, 79.1 (2018): 401-406.

SENSE based models are described in the publications K. P. Pruessmann et al.: “SENSE: sensitivity encoding for fast MRI,” Magn Reson Med. 1999 November, 42(5):952-62, K. P. Pruessmann et al.: “Advances in Sensitivity Encoding With Arbitrary k-Space Trajectories,” Magn Reson Med. 2001, 46:638-651, and M. Uecker et al.: “ESPIRIT—an eigenvalue approach to autocalibrating parallel MRI: where SENSE meets GRAPPA,” Magn Reson Med. 2014 March, 71(3):990-1001.

The publication M. W. Haskell et al.: “TArgeted Motion Estimation and Reduction (TAMER): data consistency based motion mitigation for MRI using a reduced model joint optimization.” IEEE transactions on medical imaging 37.5 (2018): 1253-1265, describes how parameters describing a rigid object motion during MR data acquisition may be used for motion compensation by minimizing a data consistency error of a SENSE forward model.

The publication D. Polak et al. “Scout accelerated motion estimation and reduction (SAMER).” Magnetic Resonance in Medicine 87.1 (2022): 163-178 describes motion estimation and reduction using a low-resolution scout scan and sequence reordering to independently determine motion states by minimizing the data-consistency error in a SENSE plus motion forward model.

The publication M. W. Haskell et al.: “Network accelerated motion estimation and reduction (NAMER): convolutional neural network guided retrospective motion correction using a separable motion model,” Magnetic resonance in medicine 82.4 (2019): 1452-1461 describes how a convolutional neural network can be trained to remove motion artifacts from 2D T2-weighted rapid acquisition with refocused echoes images and how it can be introduced into a model-based data-consistency optimization to determine motion parameters.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a schematic block diagram of an exemplary implementation of a system for MR imaging according to the disclosure;

FIG. 2 shows a schematic flow diagram of an exemplary implementation of a computer implemented method for MR image reconstruction according to the disclosure;

FIG. 3 shows a schematic flow diagram of an exemplary implementation of a computer implemented training according to the disclosure;

FIG. 4 shows a schematic representation of a convolutional neural network; and

FIG. 5 shows a schematic representation of a further convolutional neural network.

The exemplary embodiments of the present disclosure will be described with reference to the accompanying drawings. Elements, features and components that are identical, functionally identical and have the same effect are-insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the present disclosure is to overcome the problems of the related art, at least in part.

The disclosure is based on the idea to formulate the reconstruction problem such that the MLM is formally separated from terms, which are affected by the application specific parameters. The same trained MLM can then be used for various applications.

According to an aspect of the disclosure, a computer implemented method for MR image reconstruction, is provided. Therein, MR measurement data representing an imaged object is obtained and at least two iterations including an initial iteration and a final iteration are carried out in the following manner. In an exemplary embodiment, for each iteration of the at least two iterations:
a) a prior MR image for the respective iteration is received, and
b) an optimized MR image is generated by optimizing, in particular minimizing, a predefined first loss function, which depends on the MR measurement data and on the prior MR image. Furthermore,
c) an enhanced MR image is generated by applying a trained machine learning model, MLM, for image enhancement to the optimized MR image. Therein,
d) unless the respective iteration corresponds to the initial iteration of the at least two iterations, the prior MR image of the respective iteration corresponds to the enhanced MR image of a preceding iteration, in particular an iteration directly preceding the current iteration. The prior MR image of the initial iteration corresponds to a predefined initial image.

Unless stated otherwise, all steps of the computer implemented method may be performed by a data processing apparatus, which may include at least one computing unit. In particular, the at least one computing unit is configured or adapted to perform the steps of the computer implemented method. For this purpose, the at least one computing unit may for example store a computer program comprising instructions which, when executed by the at least one computing unit, cause the at least one computing unit to execute the computer implemented method.

In particular, the enhanced MR of a final iteration of the at least two iterations corresponds to a reconstructed MR image of the object.

The MLM is an MLM for image enhancement. In other words, an input to the MLM is an image, in the present case the optimized MR image, and an output of the MLM is an image as well, in the present case the enhanced MR image. Therein, the output image is enhanced with respect to the input image. What exactly is the effect of the enhancement depends on the training data and the corresponding ground truth data used for training the MLM. For example, the at training data may be intentionally corrupted or deteriorated using for example blurring filters, adding noise, and so forth. By means of the training, the MLM learns to enhance an input image accordingly.

For example, in case the MLM is an ANN, it may be a U-Net, as described in the publication of O. Ronneberger et al mentioned in the introductory part of the present disclosure, or an ANN based on the U-Net architecture.

The optimization of the first loss function may be carried out by using known optimization techniques, for example optimizations according to gradient-based techniques or the like. The optimization may, in particular be carried out iteratively itself. In this case, the at least two iterations may be considered as outer iterations, while the optimization may comprise inner iterations.

The initial image may for example be a guess for the reconstructed MR image or it may also be an image with constant pixel values everywhere, for example zero. Each iteration provides the enhanced MR image as another preliminary candidate for the reconstructed MR image, thus iteratively achieving an increased quality of the eventual reconstructed MR image as the enhanced MR image of the final iteration.

Evaluating a loss function can be understood as computing a corresponding value of loss function.

The total number of the at least two iterations is not necessarily very large, it can for example lie in the range of 2 to 20 iterations or 2 to 10 iterations or 3 to 7 iterations. Thus, the computational effort is limited.

The MR measurement data may for example be given in k-space. The data acquisition may be carried out with full sampling of the k-space or with incomplete sampling, also denoted as undersampling.

An undersampled MR data acquisition is an acquisition, whose k-space sampling scheme does not fulfil the Nyquist criterion. The k-space sampling scheme may for example be defined by a discrete function p (k), wherein k denotes coordinates, for example three-dimensional or two-dimensional coordinates, in k-space and p (k) is non-zero, for example equal to one, only at coordinates in k-space, which shall be sampled or, in other words, measured, and equal to zero otherwise.

The data acquisition may also be carried out as parallel or multi-coil acquisition, wherein the MR data are received from multiple receiver coils, which receive the MR signals emitted from the object to be imaged. In parallel imaging, the acquired multi-coil data are related to the reconstructed images through a signal model, which depends on respective coil sensitivity maps of the multiple coil channels. The MR measurement data may then comprise respective data for all coil channels and may be denoted as parallel imaging MR measurement data.

In general terms, a trained MLM may mimic cognitive functions that humans associate with other human minds. In particular, by training based on training data the MLM may be able to adapt to new circumstances and to detect and extrapolate patterns. Another term for a trained MLM is “trained function”.

In general, parameters of an MLM can be adapted by means of training. In particular, supervised training, semi-supervised training, unsupervised training, reinforcement learning and/or active learning can be used. Furthermore, representation learning, also denoted as feature learning, can be used. In particular, the parameters of the MLMs can be adapted iteratively by several steps of training. In particular, within the training a certain loss function, also denoted as cost function, can be minimized. In particular, within the training of an NN, the backpropagation algorithm can be used.

In particular, an MLM can comprise an ANN, a support vector machine, a decision tree and/or a Bayesian network, and/or the machine learning model can be based on k-means clustering, Q-learning, genetic algorithms and/or association rules. In particular, an ANN can be or comprise a deep neural network, a convolutional neural network or a convolutional deep neural network. Furthermore, an ANN can be an adversarial network, a deep adversarial network and/or a generative adversarial network.

By means of the disclosure, the trained MLM is formally separated from the first loss function. The first loss function may be adapted to various use cases or applications by including application specific parameters as if the reconstruction would be a conventional reconstruction, that is a reconstruction without using an MLM. The trained MLM itself is not affected by such modifications of the first loss function. Consequently, the same trained MLM may be used for various applications without having to be re-trained.

According to several implementations, the MLM is an ANN, for example a CNN.

According to several implementations, the MR measurement data corresponds to data measured according to at least two coil channels. In other words, the MR measurement data corresponds parallel imaging MR measurement data.

According to several implementations, the optimization of the first loss function is carried out under variation of a variable MR image, while the prior MR image is kept constant during the optimization, in particular of a given iteration.

The variable MR image can be understood as the respective optimization variables of the optimization. As a result of the optimization, the optimal variable MR image corresponds to the optimized MR image.

For example, the first loss function may include a data term, which depends on the MR measurement data and on encoded data, which is given by a predefined MR signal model matrix applied to the variable MR image.

In particular, the measurement data is parallel imaging MR measurement data in this case. The signal model matrix may also be denoted as encoding matrix. The measurement data and the variable MR image may also be given in matrix form, such that the application of the signal model matrix applied to the variable MR image corresponds to a matrix multiplication.

For example, the data term quantifies a deviation between the MR measurement data and the encoded MR data. In some implementations or use cases, respectively, the MR measurement data may be modified and the data term quantifies a deviation between the modified MR measurement data and the encoded MR data. The data term ensures data consistency and is therefore also denoted as data consistency term.

The data term may for example be given by

$${‖ Ex - y ‖}^{2}$$

wherein E denotes the signal model matrix, x denotes the variable MR image and y denotes the MR measurement data. The double vertical lines may denote the L1-norm.

For example, the signal model matrix may depends on respective predefined coil sensitivity maps for each of the at least two coil channels. The coil sensitivity maps may in general be determined by methods known in the art.

The signal model matrix may for example contain a Fourier transform and a coil sensitivity map matrix, which contains the predefined coil sensitivity maps for all coil channels. In case undersampling is used, the signal model matrix may also comprise the sampling scheme p (k). The signal model matrix may for example comprise a product of the coil sensitivity map matrix and the Fourier transform and, in case of undersampling, the sampling scheme p (k).

For example, the first loss function may comprise a regularization term, which depends on the prior MR image and the variable MR image. In particular, the regularization term quantifies a deviation between the prior MR image and variable MR image of the respective iteration.

The regularization term may for example be given by a Tikhonov regularization term. The first loss function, in particular, may comprise or consist of a sum of the data term and the regularization term.

The regularization term may for example depend on the L1-norm of the difference between the prior MR image of the respective iteration and the variable MR image. For example, the regularization term may be given by

$$\frac{1}{{λ}_{n}} {‖ x - {x}_{n} ‖}^{2} ,$$

wherein n denotes the respective iteration, xₙ denotes the prior MR image of the respective iteration, and λₙ denotes a regularization weight. The regularization weight may be the same for all of the at least two iterations or it may be different for different iterations.

According to several implementations, a point spread function for a data acquisition process used for generating the MR measurement data is received and the signal model matrix depends on the point spread function.

The point spread function describes, how a hypothetical point-like object would be imaged after reconstruction. In general, such a point-like object does not appear as an exact point in the reconstructed MR image but appears blurred. Considering a real object to be composed of multiple point-like objects, the point spread function may predict how the object appears in the reconstructed MR image.

The point spread function generally depends fundamentally on the used acquisition process. In respective implementations of the disclosure, this dependency is treated separately from the MLM part of the reconstruction allowing for various different applications using the same trained MLM.

The point spread function depends, in particular, on coefficients defining the data acquisition process. For example, the data acquisition process is a CAIPIRINHA acquisition, in particular a Wave-CAIPI acquisition. It is referred to the publication of D. Polak et al. “Wave-CAIPI [ . . . ]” mentioned above for further details.

According to several implementations, the signal model matrix depends on translation offsets describing a rigid motion of the imaged object and/or the signal model matrix depends on rotation angles describing the rigid motion of the imaged object. In particular, the signal model matrix depends on the respective translation offsets and/or rotation angles for each sampled k-space position.

Compensation of rigid motion of the imaged object is a well-known problem in MR imaging and various approaches are known to solve it.

In particular, for rigid motion, for which the current motion position may be characterized by six parameters, namely three translation offsets and three rotation angles. The may be integrated into the signal model matrix to consider the motion effects in the reconstruction.

The parameters, namely translation offsets and/or rotation angles, may be determined through joint iteration of image and parameters as described in the publication of M. W. Haskell et al.

“TArgeted Motion [ . . . ]” mentioned above. The parameters may also be precalculated by correlation with a scout acquisition, as described in the publication of D. Polak et al. “Scout accelerated [ . . . ]” mentioned above. The parameters may also be estimated with the help of an ANN, which is independent of the MLM, as described in the publication of M. W. Haskell et al. “Network accelerated [ . . . ]” mentioned above.

In such implementations, the disclosure allows to use the same trained MLM for reconstructions with and without considering rigid motion compensation and also for different methods to consider the rigid motion.

According to several implementations, the signal model matrix depends on a deformation vector field describing a non-rigid deformation of the imaged object.

Compensation of non-rigid motion of the imaged object is a well-known problem in MR imaging and various approaches are known to solve it. The non-rigid motion corresponds, for example, to a deformation of patient tissues due to respiratory and/or cardiac motion.

In this case, the acquired data may be assigned to motion states or motion phases. The corresponding images are related by an elastic warping, which can be included in the signal model matrix by introducing the respective parameters parameterizing the deformation vector fields.

In such implementations, the disclosure allows to use the same trained MLM for reconstructions with and without considering non-rigid motion compensation and also for different methods to consider the non-rigid motion.

According to a further aspect of the disclosure, a method for MR image reconstruction is provided. Therein, the MR measurement data representing an imaged object is generated by an MRI scanner and a computer implemented method for MR image reconstruction according to the disclosure is carried out.

According to a further aspect of the disclosure, Computer implemented training method for training an MLM for image enhancement for use in a computer implemented method for MR image reconstruction according to the disclosure is provided. Therein, training MR data is received, and a ground truth reconstructed MR image corresponding to the training MR data is received. At least two training iterations including an initial training iteration and a final training iteration are carried out as follows. For each training iteration of the at least two training iterations,
a′) a training prior MR image for the respective training iteration is received, and
b′) an optimized training MR image is generated by optimizing a predefined second loss function, which depends on the training MR data and on the training prior MR image.
c′) An enhanced training MR image is generated by applying the MLM to the optimized training MR image. Therein,
d′) unless the respective training iteration corresponds to the initial training iteration, the training prior MR image of the respective training iteration corresponds to the enhanced training MR image of a preceding training iteration. The training prior MR image of the initial training iteration corresponds to a predefined initial training image.

A predefined third loss function is evaluated depending on the enhanced training MR image of the final training iteration and the ground truth reconstructed MR image. The MLM is updated depending on a result of the evaluation of the third loss function.

As mentioned above, the output image of MLM is enhanced with respect to its input image. What exactly is the effect of the enhancement depends on the training MR measurement data and the ground truth reconstructed MR image. For example, the training MR data may be intentionally corrupted or deteriorated using for example blurring filters, adding noise, and so forth. By means of the training, the MLM learns to enhance an input image accordingly.

The input to the MLM, for example the ANN, is the optimized MR image of the respective training iteration and its output is the enhanced MR image. However, the evaluation of the third loss function is not carried out for each iteration but only after all of the two or more iterations have been carried out. Thus, also the optimization of the step b′) is included in the training process, which leads to an increased training efficiency.

The MLM may for example be an ANN, in particular a CNN, for example a U-Net or an architecture based on the U-Net. In this case, updating the MLM can be understood as updating network parameters, in particular network weights and/or bias factors, of the ANN. The updating may be done by using known algorithms, such as backpropagation.

The third loss function may also be a known loss function used for training image enhancement ANNs, such as for example a pixel-wise loss function, for example an L1-loss function or an L2-loss function.

The described steps including the at least two iterations, the evaluation of the third loss function, and the update of the MLM are, in particular, understood as a single training run. A plurality of such runs may be carried out consecutively, until a predetermined termination or convergence criterion regarding the second loss function is reached. Each set of at least one training image may be denoted as a training sample. The number of training samples may lie in the order of 10000 or several times 10000. The number of training epochs may for example lie in the order 100-1000. The total number of training runs is for example given by the product of the number of training samples and the number of training epochs.

It is noted that the application specific parameters, for example parameters of the point spread function of the acquisition process for generating the MR measurement data, parameters specifying the rigid or non-rigid motion, and so forth, are not necessarily considered for training the MLM, in particular are not necessarily contained in the second loss function.

According to several implementations, the ground truth reconstructed MR image is generated assuming full k-space sampling.

According to several implementations, the optimization of the second loss function is carried out under variation of a variable MR image, while the training prior MR image is kept constant during the optimization. The second loss function may include a data term, which depends on the training MR data and on further encoded data, which is given by a predefined further MR signal model matrix applied to the variable MR image.

According to several implementations, the second loss function may include a regularization term, which depends on the prior MR image and the variable MR image.

In particular, the second loss function may be identical to the first loss function without considering the application specific parameters.

According to several implementations of the computer implemented method for MR image reconstruction, the MLM is trained or has been trained by using a computer implemented training method according to the disclosure.

The computer implemented method for MR image reconstruction may, in some implementations, comprise training the MLM by using a computer implemented training method according to the disclosure. In other implementations, the computer implemented method for MR image reconstruction does not include the steps of the computer implemented training method.

According to several implementations of the computer implemented method for MR image reconstruction, the MLM is trained by using a computer implemented training according to the disclosure. The computer implemented method for MR image reconstruction is carried out such that the point spread function for the data acquisition process used for generating the MR measurement data is received and the signal model matrix used for the MR image reconstruction depends on the point spread function. The further MR signal model matrix used for the training is independent of the point spread function.

According to several implementations of the computer implemented method for MR image reconstruction, the MLM is trained by using a computer implemented training according to the disclosure. The computer implemented method for MR image reconstruction is carried out such that the signal model matrix depends on the translation offsets and/or the signal model matrix depends on the rotation angles describing the rigid motion of the imaged object. The further MR signal model matrix is independent of the translation offsets and independent of the rotation angles.

According to several implementations of the computer implemented method for MR image reconstruction, the MLM is trained by using a computer implemented training according to the disclosure. The computer implemented method for MR image reconstruction is carried out such that the signal model matrix depends on the deformation vector field describing the non-rigid deformation of the imaged object. The further MR signal model matrix is independent of the deformation vector field.

According to a further aspect of the disclosure, a data processing apparatus comprising at least one computing unit is provided. The at least one computing unit is adapted to carry out a computer implemented training method according to the disclosure and/or a computer implemented method for MR image reconstruction according to the disclosure.

A computing unit (also referred to as a computer) may in particular be understood as a data processing device, which may include processing circuitry. The computing unit may be configured to process data to perform computing operations. This may also include operations to perform indexed accesses to a data structure, for example a look-up table, LUT.

In particular, the computing unit may include one or more computers, one or more microcontrollers, and/or one or more integrated circuits, for example, one or more application-specific integrated circuits, ASIC, one or more field-programmable gate arrays, FPGA, and/or one or more systems on a chip, SoC. The computing unit may additionally or alternatively include one or more processors, for example one or more microprocessors, one or more central processing units, CPU, one or more graphics processing units, GPU, and/or one or more signal processors, in particular one or more digital signal processors, DSP. The computing unit may additionally or alternatively include a physical or a virtual cluster of computers or other of the units.

In various embodiments, the computing unit may include one or more hardware and/or software interfaces, and/or one or more memory units.

A memory unit may be implemented as a volatile data memory, for example a dynamic random access memory, DRAM, or a static random access memory, SRAM, or as a non-volatile data memory, for example a read-only memory, ROM, a programmable read-only memory, PROM, an erasable programmable read-only memory, EPROM, an electrically erasable programmable read-only memory, EEPROM, a flash memory or flash EEPROM, a ferroelectric random access memory, FRAM, a magnetoresistive random access memory, MRAM, or a phase-change random access memory, PCRAM.

According to a further aspect of the disclosure, a system for MR imaging is provided. The system may include a data processing apparatus according to the disclosure, wherein the at least one computing unit is adapted carry out a computer implemented method for MR image reconstruction according to the disclosure. The system may include an MRI scanner. The at least one computing unit is adapted to control the MRI scanner to generate the at least two measured MR images.

According to a further aspect of the disclosure, a first computer program comprising first instructions is provided. When the first instructions are executed by a data processing apparatus, the first instructions cause the data processing apparatus to carry out a computer implemented training method according to the disclosure.

The first instructions may be provided as program code, for example. The program code can for example be provided as binary code or assembler and/or as source code of a programming language, for example C, and/or as program script, for example Python.

According to a further aspect of the disclosure, a second computer program comprising second instructions is provided. When the second instructions are executed by a data processing apparatus, the second instructions cause the data processing apparatus to carry out a computer implemented method for MR image reconstruction according to the disclosure.

The second instructions may be provided as program code, for example. The program code can for example be provided as binary code or assembler and/or as source code of a programming language, for example C, and/or as program script, for example Python.

According to a further aspect of the disclosure, a computer-readable storage medium, in particular a tangible and non-transient computer-readable storage medium, storing a first computer program and/or a second computer program according to the disclosure is provided.

The first computer program, the second computer program and the computer-readable storage medium are respective computer program products comprising the first instructions and/or the second instructions.

Further features and feature combinations of the disclosure are obtained from the figures and their description as well as the claims. In particular, further implementations of the disclosure may not necessarily contain all features of one of the claims. Further implementations of the disclosure may comprise features or combinations of features, which are not recited in the claims.

Above and in the following, the solution according to the disclosure is described with respect to the claimed systems as well as with respect to the claimed methods. Features, advantages or alternative embodiments herein can be assigned to the other claimed objects and vice versa. In other words, claims and embodiments for the systems can be improved with features described or claimed in the context of the respective methods. In this case, the functional features of the method are implemented by physical units of the system.

Furthermore, above and in the following, the solution according to the disclosure is described with respect to methods and systems for MR image reconstruction as well as with respect to methods and systems for providing a trained MLM. Features, advantages or alternative embodiments herein can be assigned to the other claimed objects and vice versa. In other words, claims and embodiments for providing a trained MLM can be improved with features described or claimed in the context of MR image reconstruction. In particular, datasets used in the methods and systems can have the same properties and features as the corresponding datasets used in the methods and systems for providing a trained MLM, and the trained MLMs provided by the respective methods and systems can be used in the methods and systems for MR image reconstruction.

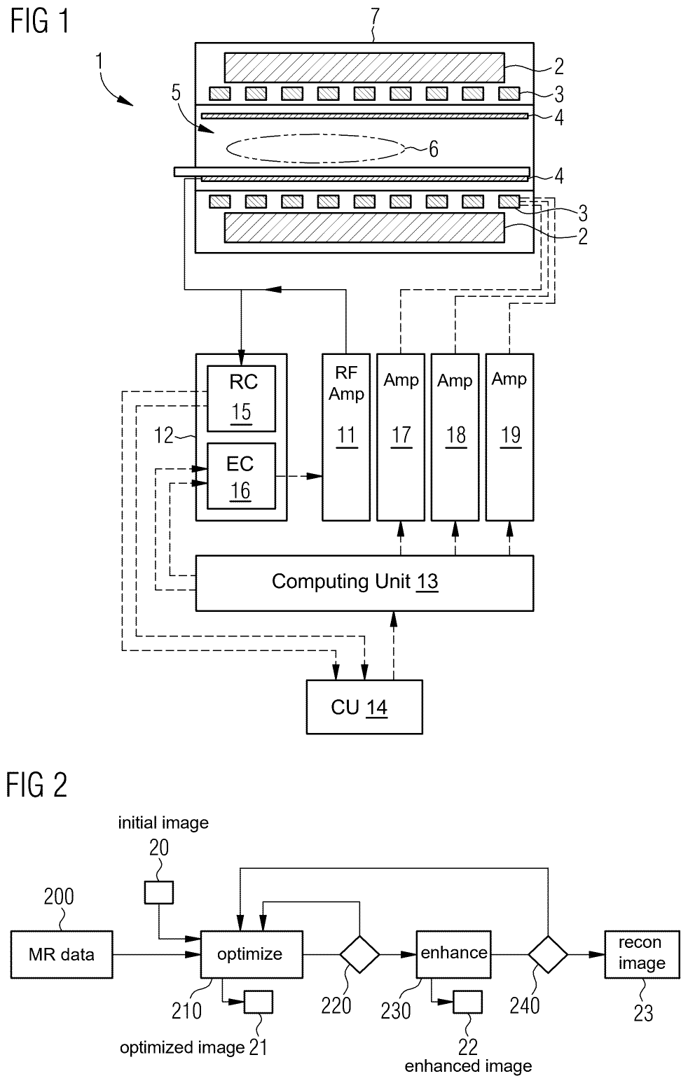

FIG. 1 shows schematically an exemplary implementation of a system for MR imaging, also denoted as MRI system 1, according to the disclosure. The MRI system 1 may include a housing 7 defining a bore 5 and a main magnet arrangement 2, which is configured to generate a main magnetic field, also denoted as polarizing magnetic field, within the bore 5. The MRI system 1 may include an RF system 4, 11, 12, which is configured to apply an asymmetric RF pulse to a target material, in particular a body part of a patient 6, disposed within the bore 5 and to receive MR signals from the target material. For example, the main magnet arrangement 2 may generate a uniform main magnetic field B0 as the main magnetic field and at least one RF coil 4 of the RF system 4, 11, 12 may emit an excitation field B1. The MRI system 1 may include a data processing apparatus with at least one computing unit 13, 14, which is configured to construct the asymmetric RF pulse by using a computer implemented method for constructing an asymmetric RF pulse according to the present disclosure.

To this end, the at least one computing unit 13, 14 determines a first RF amplitude for a predefined first part of a predefined time interval, and receives an RF amplitude curve, which depends on at least one RF curve parameter. The at least one computing unit 13, 14 determines a combined RF amplitude curve for the time interval by combining, in particular concatenating, the first RF amplitude for the first part of the time interval and the RF amplitude curve for a predefined second part of the time interval, which succeeds the first part of the time interval. The at least one computing unit 13, 14 carries out an optimization to optimize the combined RF amplitude curve using a loss function, which may include an energy loss term, which depends on a pulse energy of the combined RF amplitude curve, and using the at least one RF curve parameter as at least one optimization variable. The at least one computing unit 13, 14 determines the asymmetric RF pulse, wherein a combined amplitude of the asymmetric RF pulse for the time interval is given by the optimized combined RF amplitude curve.

According to MR techniques, the target material is subjected to the main magnetic field, causing the nuclear spins in the target material to precess about the main magnetic field at their characteristic Larmor frequency. A net magnetic moment Mz is produced in the direction z of the main magnetic field, and the randomly oriented magnetic moments of the nuclear spins cancel out one another in the x-y-plane.

When the target material is then subjected to the transmit RF magnetic field, which is for example in the x-y plane and near the Larmor frequency, the net magnetic moment rotates out of the z-direction generating a net in-plane magnetic moment, which rotates in the x-y plane with the Larmor frequency. In response, MR signals are emitted by the excited spins when they return to their state before the excitation. The emitted MR signals are detected, for example by the at least one RF coil 4 and/or one or more dedicated detection coils, digitized in a receiver channel 15 of an RF controller 12 of the RF system 4, 11, 12, and processed by at least one processor 14 of the at least one computing unit 13, 14 to reconstruct an MR image using for example a computer implemented method for MR image reconstruction according to the disclosure.

In particular, gradient coils 3 of the MRI system 1 may produce magnetic field gradients Gx, Gy, and Gz for position-encoding of the MR signals. Accordingly, MR signals are emitted only by such nuclei of the target material, which correspond to the particular Larmor frequency. For example, Gz is used together with a bandwidth-limited RF pulse to select a slice perpendicular to the z-direction and consequently may also be denoted as slice selection gradient. In alternative example, Gx, Gy, and Gz may be used in any predefined combination with a bandwidth-limited RF pulse to select a slice perpendicular to the vector sum of the gradient combination. The gradient coils 3 may be supplied with current by respective amplifiers 17, 18, 19 for generating the respective gradient fields in x-direction, y-direction, and z-direction, respectively. Each amplifier 17, 18, 19 may include a respective digital-to-analog converter, which is controlled by the sequence controller 13 to generate respective gradient pulses at predefined time instances.

It is noted that the components of the MRI system 1 can also be arranged differently from the arrangement shown in FIG. 1. For example, the gradient coils 3 may be arranged inside the bore 5, similar as shown for the at least one RF coil 4.

A sequence controller 13 of the at least one computing unit 13, 14 may control the generation of RF pulses by an emitter channel 16 of the RF controller 12 and an RF power amplifier 11 of the RF system 4, 11, 12.

The least one processor 14 may receive the real and imaginary parts from analog-digital converters of the receiver channel 15 and reconstruct the MR image based on them.

It is noted that each component of the MRI system 1 may include other elements which are required for the operation thereof, and/or additional elements for providing functions other than those described in the present disclosure.

FIG. 2 shows a schematic flow diagram of an exemplary implementation of a computer implemented method for MR image reconstruction according to the disclosure.

In step 200 MR measurement data representing an imaged object 6 is obtained, in particular from the MRI system 1. For each iteration of at least two iterations, a prior MR image for the respective iteration is received. The prior MR image of an initial iteration of the at least two iterations is given by a predefined initial image 20. In steps 210 and 220, an optimized MR image 21 is generated by optimizing a predefined first loss function, which depends on the MR measurement data and on the prior MR image. The optimization may be carried out iteratively as well. Step 210 then corresponds to an optimization step, while in step 220, it is determined whether a termination or convergence criterion for the optimization is reached. If this is not the case, another optimization step 210 is carried out, otherwise the optimized MR image 21 is further processed in step 230.

In step 230, an enhanced MR image 22 is generated by applying the trained MLM to the optimized MR image 21. The prior MR image of the respective iteration is given by the enhanced MR image 22 of the corresponding preceding iteration, unless the respective iteration corresponds to the initial iteration. In step 240, it is determined whether a predefined total number of the at least two iterations has been carried out. If this is not the case, the next iteration is carried out.

Otherwise, the reconstructed MR image 23 is determined as the enhanced MR image 22 of a final iteration of the at least two iterations.

MR image reconstruction can be based on a signal model matrix or encoding matrix E that connects the reconstructed image x to the acquired MR measurement data y. It may involve modeling of the coil sensitivity maps, a Fourier transformation and the k-space trajectory of the acquisition. The data consistency can then be measured through the cost function

$$L = {‖ Ex - y ‖}^{2} . \qquad [ 1 ]$$

Since the signal model matrix may be imperfect and not perfectly conditioned, one may use additional prior information or regularization. Particularly deep learning has provided big improvements in image quality and significant acceleration of scans.

According to several implementations of the disclosure, a deep learning based reconstruction is employed, which iteratively calculates images Xn by alternating between data consistency updates, for example in the negative direction of the loss function's gradient, and image regularization by the MLM, which is for example a CNN, in particular a U-Net based CNN, for image enhancement. Several implementations of the disclosure make use of a formulation, wherein these two types of steps are split according to

$${x}_{n + 1 / 2} = {argmin}_{x} ( {‖ Ex - y ‖}^{2} - \frac{1}{{λ}_{n}} {‖ x - {x}_{n} ‖}^{2} ) \qquad [ 2.1 ]$$

$${x}_{n + 1} = {R}_{n} ( {x}_{n + 1 / 2} ) . \qquad [ 2.2 ]$$

Therein, n∈[0, N) iterations are sequentially performed to provide the final reconstructed MR image X_{N}. The initial prior image x₀ may be a guess or identical to zero, for example. λₙ are

Lagrange multipliers that may be determined within the training and Rₙ is the trained MLM for image enhancement. The coefficients λₙ provide an interpolation between the current prior image xₙ at λₙ=0 and the parallel imaging solution at λₙ=∞. In conventional reconstructions they correspond to a Tikhonov regularization.

In particular for rigid motion, for which the current motion position is characterized by six parameters, namely three translation offsets and three rotation angles, the motion can be considered in the reconstruction. In this case the signal model matrix includes the motion correction for each k-space sample. The additional parameters may be labeled as 0 and the cost function is generalized to

$$L = {‖ {E}_{θ} x - y ‖}^{2} . \qquad [ 3 ]$$

The parameters θ may for example be determined through joint iteration of image and parameters, pre-calculated by correlation with a scout acquisition or determined with help of a neural network, which is not related to the MLM, however, but only used for determining the parameters θ.

In the variable splitting approach, the optimization is extended to
to

$${x}_{n + 1 / 2} = {argmin}_{x} ( {‖ {E}_{θ} x - y ‖}^{2} - \frac{1}{{λ}_{n}} {‖ x - {x}_{n} ‖}^{2} ) \qquad [ 4.1 ]$$

$${x}_{n + 1} = {R}_{n} ( {x}_{n + 1 / 2} ) . \qquad [ 4.2 ]$$

Similarly, there are other acquisition types such as Wave-CAIPI, where the conventional reconstruction is of the form of equation [3], namely

$$L = {‖ {E}_{γ} x - y ‖}^{2} , \qquad [ 5 ]$$

where γ denotes the coefficients of the point-spread function. Similarly, the reconstruction can be combined with a deep learning-based reconstruction
to

$${x}_{n + 1 / 2} = {argmin}_{x} ( {‖ {E}_{γ} x - y ‖}^{2} - \frac{1}{{λ}_{n}} {‖ x - {x}_{n} ‖}^{2} ) \qquad [ 6.1 ]$$

$${x}_{n + 1} = {R}_{n} ( {x}_{n + 1 / 2} ) . \qquad [ 6.2 ]$$

The reconstruction may for example be trained based on a conventional CAIPIRINHA sampling pattern.

For cardiac imaging and abdominal images, for example, the MR measurement data may be assigned to motion states or phases. The corresponding images are related by an elastic warping which can be included in the encoding matrix. In this case the parameters included into E parameterize the motion vector fields.

According to several implementations, a DL reconstruction that involves the optimization of a data consistency term which amounts to a conventional, regularized parallel imaging reconstruction is provided and during inference, this component is replaced by a reconstruction term with additional parameters.

According to several implementations, the architecture of the DL reconstruction involves variable splitting and alternates between a conventional parallel imaging reconstruction and a network regularization using the MLM.

According to several implementations, a conventional parallel imaging reconstruction is performed iteratively and for a single outer iteration, few inner iterations are performed. In total, the iterations are sufficient for the convergence of the conventional reconstruction. In this way, the network regularizations are weaved into the conventional reconstruction.

According to several implementations, additional application specific parameters, which are associated with motion correction, are considered in the signal model matrix.

According to several implementations, additional application specific parameters, which are associated with assignment to motion states or phases, are considered in the signal model matrix.

According to several implementations, additional application specific parameters, which are associated with corrupted data, such as spikes, are considered in the signal model matrix.

According to several implementations, additional application specific parameters, which are associated with weighting parameters of the sampling in the loss function, are considered in the signal model matrix.

According to several implementations, the additional application specific parameters are only determined at the beginning of the reconstruction or at few points in the reconstruction process.

According to several implementations, the additional application specific parameters are determined by an ANN, which is trained for example in a supervised manner using augmented training data.

According to several implementations, the DL reconstruction that is trained on non-corrupted data including a step with a conventional, regularized parallel imaging reconstruction and the conventional, regularized parallel imaging reconstruction is replaced by a more involved reconstruction to correct additional effects during inference.

According to several implementations, the DL reconstruction is trained with augmented data and includes adverse effects during training.

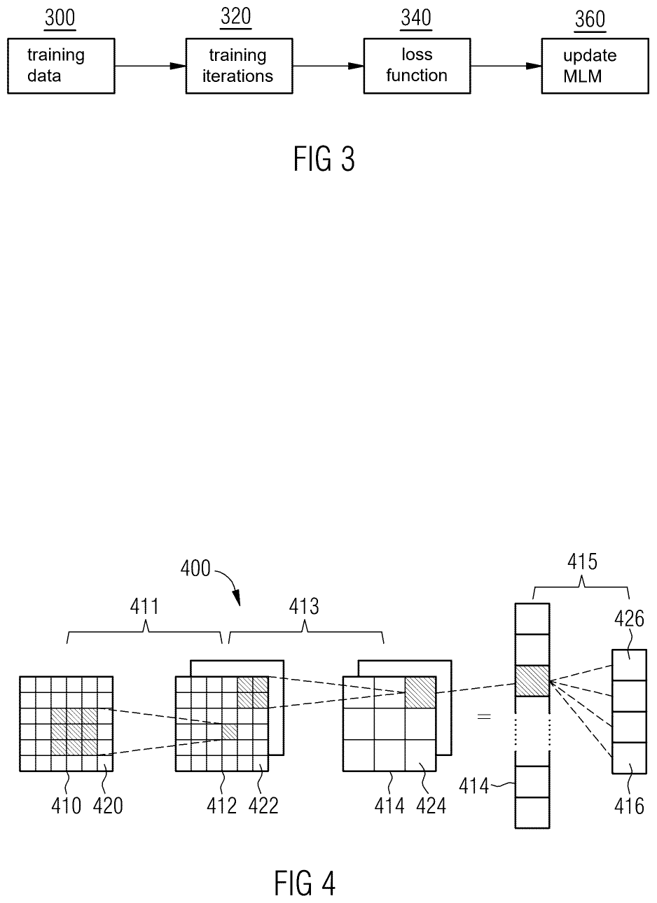

FIG. 3 shows a schematic flow diagram of an exemplary implementation of a computer implemented training according to the disclosure.

In step 300, training MR data is received, and a ground truth reconstructed MR image corresponding to the training MR data is received. In step 320, at least two training iterations are carried out, similar as described with respect to FIG. 2. For each training iteration of the at least two training iterations, a training prior MR image for the respective training iteration is received, an optimized training MR image is generated by optimizing a predefined second loss function, which depends on the training MR data and on the training prior MR image, and an enhanced training MR image is generated by applying the MLM to the optimized training MR image. The training prior MR image of the respective training iteration corresponds to the enhanced training MR image of a preceding training iteration, unless the respective training iteration corresponds to an initial training iteration of the at least two training iterations, and the training prior MR image of the initial training iteration corresponds to a predefined initial training image.

In step 340, a predefined third loss function is evaluated depending on the enhanced training MR image of a final training iteration of the at least two training iterations and the ground truth reconstructed MR image. In step 360, the MLM is updated depending on a result of the evaluation of the third loss function.

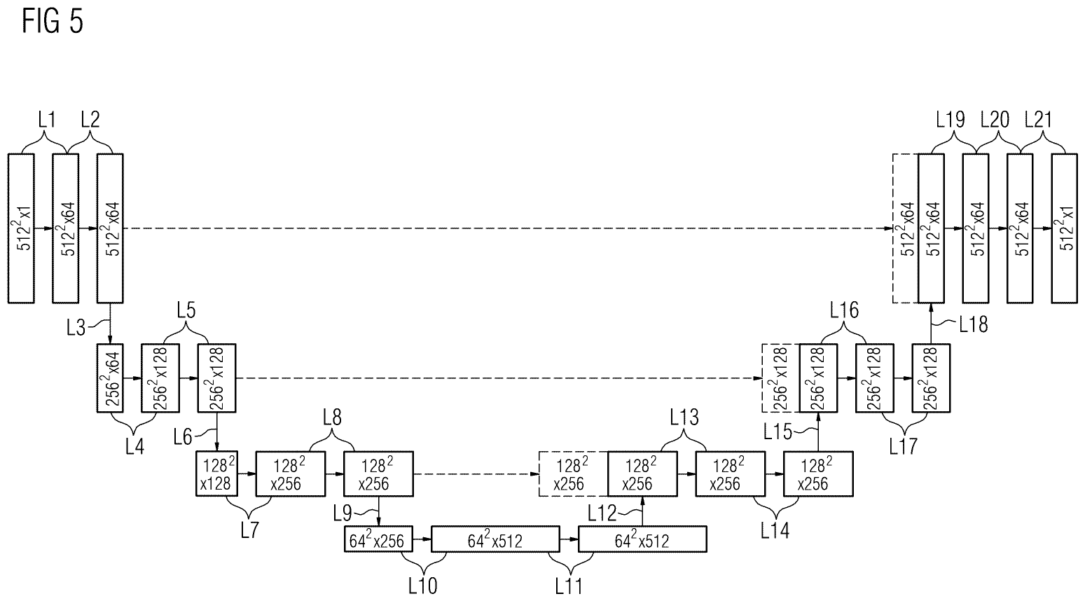

The MLM may for example be an ANN, in particular a CNN, as schematically depicted in FIG. 4, FIG. 5.

A CNN is an ANN that uses a convolution operation instead general matrix multiplication in at least one of its layers. These layers are denoted as convolutional layers. In particular, a convolutional layer performs a dot product of one or more convolution kernels with the convolutional layer's input data, wherein the entries of the one or more convolution kernel are parameters or weights that may be adapted by training. In particular, one can use the Frobenius inner product and the ReLU activation function. A convolutional neural network can comprise additional layers, for example pooling layers, fully connected layers, and/or normalization layers.

By using convolutional neural networks, the input can be processed in a very efficient way, because a convolution operation based on different kernels can extract various image features, so that by adapting the weights of the convolution kernel the relevant image features can be found during training. Furthermore, based on the weight-sharing in the convolutional kernels less parameters need to be trained, which prevents overfitting in the training phase and allows to have faster training or more layers in the network, improving the performance of the network.

FIG. 4 displays an exemplary embodiment of a convolutional neural network 400. In the displayed embodiment, the convolutional neural network 400 may include an input node layer 410, a convolutional layer 411, a pooling layer 413, a fully connected layer 414 and an output node layer 416, as well as hidden node layers 412, 414. Alternatively, the convolutional neural network 400 can comprise several convolutional layers 411, several pooling layers 413 and/or several fully connected layers 415, as well as other types of layers. The order of the layers can be chosen arbitrarily, usually fully connected layers 415 are used as the last layers before the output layer 416.

In particular, within a convolutional neural network 400 nodes 420, 422, 424 of a node layer 410, 412, 414 can be considered to be arranged as a d-dimensional matrix or as a d-dimensional image. In particular, in the two-dimensional case the value of the node 420, 422, 424 indexed with i and j in the n-th node layer 410, 412, 414 can be denoted as x(n)[i, j]. However, the arrangement of the nodes 420, 422, 424 of one node layer 410, 412, 414 does not have an effect on the calculations executed within the convolutional neural network 400 as such, since these are given solely by the structure and the weights of the edges.

A convolutional layer 411 is a connection layer between an anterior node layer 410 with node values x(n−1) and a posterior node layer 412 with node values x(n). In particular, a convolutional layer 411 is characterized by the structure and the weights of the incoming edges forming a convolution operation based on a certain number of kernels. In particular, the structure and the weights of the edges of the convolutional layer 411 are chosen such that the values x(n) of the nodes 422 of the posterior node layer 412 are calculated as a convolution x(n)=K*x(n−1) based on the values x(n−1) of the nodes 420 anterior node layer 410, where the convolution * is defined in the two-dimensional case as

$${x}^{( n )} [ i , j ] = ( K * {x}^{( n - 1 )} ) [ i , j ] = {\sum }_{{i}^{′}} {\sum }_{{j}^{′}} K [ {i}^{′} , {j}^{′} ] \cdot {x}^{( n - 1 )} [ i - {i}^{′} , j - {j}^{′} ] .$$

Herein, the kernel K is a d-dimensional matrix, in the present example a two-dimensional matrix, which is usually small compared to the number of nodes 420, 422, for example a 3×3 matrix, or a 5×5 matrix. In particular, this implies that the weights of the edges in the convolution layer 411 are not independent, but chosen such that they produce the convolution equation. In particular, for a kernel being a 3×3 matrix, there are only 9 independent weights, each entry of the kernel matrix corresponding to one independent weight, irrespectively of the number of nodes 420, 422 in the anterior node layer 410 and the posterior node layer 412.

In general, convolutional neural networks 400 use node layers 410, 412, 414 with a plurality of channels, in particular, due to the use of a plurality of kernels in convolutional layers 411. In those cases, the node layers can be considered as (d+1)-dimensional matrices, the first dimension indexing the channels. The action of a convolutional layer 411 is then in a two-dimensional example defined as

$${x}_{b}^{( n )} [ i , j ] = {\sum }_{a} ( {K}_{a , b} * {x}_{a}^{( n - 1 )} [ i , j ] = {\sum }_{a} {\sum }_{{i}^{′}} {\sum }_{{j}^{′}} {K}_{a , b} [ {i}^{′} , {j}^{′} ] \cdot {x}_{a}^{( n - 1 )} [ i - {i}^{′} , j - {j}^{′} ] ,$$

wherein xₐ⁽ⁿ⁾ corresponds to the a-th channel of the anterior node layer 410, x_{b}⁽ⁿ⁾ corresponds to the b-th channel of the posterior node layer 412 and K_{a,b} corresponds to one of the kernels. If a convolutional layer 411 acts on an anterior node layer 410 with A channels and outputs a posterior node layer 412 with B channels, there are A·B independent d-dimensional kernels K_{a,b}.

In general, in convolutional neural networks 400 activation functions may be used. In this embodiment, ReLU (rectified linear unit) is used, with R(z)=max(0, z), so that the action of the convolutional layer 411 in the two-dimensional example is

$${x}_{b}^{( n )} [ i , j ] = R ( {\sum }_{a} ( {K}_{a , b} * {x}_{a}^{( n - 1 )} [ i , j ] ) = R ( {\sum }_{a} {\sum }_{{i}^{′}} {\sum }_{{j}^{′}} {K}_{a , b} [ {i}^{′} , {j}^{′} ] \cdot {x}_{a}^{( n - 1 )} [ i - {i}^{′} , j - {j}^{′} ] ) .$$

It is also possible to use other activation functions, for example ELU (exponential linear unit), LeakyReLU, Sigmoid, Tan h or Softmax.

In the displayed embodiment, the input layer 410 comprises 36 nodes 420, arranged as a two-dimensional 6×6 matrix. The first hidden node layer 412 comprises 72 nodes 422, arranged as two two-dimensional 6×6 matrices, each of the two matrices being the result of a convolution of the values of the input layer with a 3×3 kernel within the convolutional layer 411. Equivalently, the nodes 422 of the first hidden node layer 412 can be interpreted as arranged as a three-dimensional 2×6×6 matrix, wherein the first dimension correspond to the channel dimension.

An advantage of using convolutional layers 411 is that spatially local correlation of the input data can exploited by enforcing a local connectivity pattern between nodes of adjacent layers, in particular by each node being connected to only a small region of the nodes of the preceding layer.

A pooling layer 413 is a connection layer between an anterior node layer 412 with node values x(n−1) and a posterior node layer 414 with node values x(n). In particular, a pooling layer 413 can be characterized by the structure and the weights of the edges and the activation function forming a pooling operation based on a non-linear pooling function f. For example, in the two-dimensional case the values x(n) of the nodes 424 of the posterior node layer 414 can be calculated based on the values x(n−1) of the nodes 422 of the anterior node layer 412 as

$${x}_{b}^{( n )} [ i , j ] = f ( {x}_{b}^{( n - 1 )} [ {id}_{1} , {jd}_{2} ] , … , {x}_{b}^{( n - 1 )} [ ( i + 1 ) {d}_{1} - 1 , ( j + 1 ) {d}_{2} - 1 ] ) .$$

In other words, by using a pooling layer 413, the number of nodes 422, 424 can be reduced by re-placing a number d1·d2 of neighboring nodes 422 in the anterior node layer 412 with a single node 422 in the posterior node layer 414 being calculated as a function of the values of the number of neighboring nodes. In particular, the pooling function f can be the max-function, the average, or the L2-Norm. In particular, for a pooling layer 413 the weights of the incoming edges are fixed and are not modified by training.

The advantage of using a pooling layer 413 is that the number of nodes 422, 424 and the number of parameters is reduced. This leads to the amount of computation in the network being reduced and to a control of overfitting.

In the displayed embodiment, the pooling layer 413 is a max-pooling layer, replacing four neighboring nodes with only one node, the value being the maximum of the values of the four neighboring nodes. The max-pooling is applied to each d-dimensional matrix of the previous layer. In this embodiment, the max-pooling is applied to each of the two two-dimensional matrices, reducing the number of nodes from 72 to 18.

In general, the last layers of a convolutional neural network 400 may be fully connected layers 415. A fully connected layer 415 is a connection layer between an anterior node layer 414 and a posterior node layer 416. A fully connected layer 413 can be characterized by the fact that a majority, in particular, all edges between nodes 414 of the anterior node layer 414 and the nodes 416 of the posterior node layer are present, and wherein the weight of each of these edges can be adjusted individually.

In this embodiment, the nodes 424 of the anterior node layer 414 of the fully connected layer 415 are displayed both as two-dimensional matrices, and additionally as non-related nodes, indicated as a line of nodes, wherein the number of nodes was reduced for a better presentability. This operation is also denoted as flattening. In this embodiment, the number of nodes 426 in the posterior node layer 416 of the fully connected layer 415 smaller than the number of nodes 424 in the anterior node layer 414. Alternatively, the number of nodes 426 can be equal or larger.

Furthermore, in this embodiment the Softmax activation function is used within the fully connected layer 415. By applying the Softmax function, the sum the values of all nodes 426 of the output layer 416 is 1, and all values of all nodes 426 of the output layer 416 are real numbers between 0 and 1. In particular, if using the convolutional neural network 400 for categorizing input data, the values of the output layer 416 can be interpreted as the probability of the input data falling into one of the different categories.

In particular, convolutional neural networks 400 can be trained based on the backpropagation algorithm. For preventing overfitting, methods of regularization can be used, for example dropout of nodes 420, . . . , 424, stochastic pooling, use of artificial data, weight decay based on the L1 or the L2 norm, or max norm constraints.

In the example of FIG. 5, the MLM is a CNN, in particular, a convolutional neural network having a U-net structure. In the displayed example, the input data to the CNN is a two-dimensional medical image comprising 512×512 pixels, every pixel comprising one intensity value. The CNN comprises convolutional layers indicated by solid, horizontal arrows, pooling layers indicating by solid arrows pointing down, and upsampling layers indicated by solid arrows pointing up. The number of the respective nodes is indicated within the boxes. Within the U-net structure first the input images are downsampled, in particular by decreasing the size of the images and increasing the number of channels. Afterwards they are upsampled, in particular by increasing the size of the images and decreasing the number of channels, to generate a transformed image.

All except the last convolutional layers L1, L2, L4, L5, L7, L8, L10, L11, L13, L14, L16, L17, L19, L20 use 3×3 kernels with a padding of 1, the ReLU activation function, and a number of filters or convolutional kernels that matches the number of channels of the respective node layers as indicated in FIG. 5. The last convolutional layer uses a 1×1 kernel with no padding and the ReLU activation function.

The pooling layers L3, L6, L9 are max-pooling layers, replacing four neighboring nodes with only one node, the value being the maximum of the values of the four neighboring nodes. The upsampling layers L12, L15, L18 are transposed convolution layers with 3×3 kernels and stride 2, which effectively quadruple the number of nodes. The dashed horizontal errors correspond to concatenation operations, where the output of a convolutional layer L2, L5, L8 of the downsampling branch of the U-net structure is used as additional inputs for a convolutional layer L13, L16, L19 of the upsampling branch of the U-net structure. This additional input data is treated as additional channels in the input node layer for the convolutional layer L13, L16, L19 of the upsampling branch.

Independent of the grammatical term usage, individuals with male, female or other gender identities are included within the term.

To enable those skilled in the art to better understand the solution of the present disclosure, the technical solution in the embodiments of the present disclosure is described clearly and completely below in conjunction with the drawings in the embodiments of the present disclosure.

Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein.

Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A computer implemented method for magnetic resonance (MR) image reconstruction, comprising:
obtaining MR measurement data representing an imaged object; and
generating a reconstructed MR image based on the MR measurement data, wherein the generation of the reconstructed MR image includes performing least two reconstruction iterations, for each iteration of the at least two reconstruction iterations:
a) receiving a prior MR image for the respective iteration;
b) optimizing a predefined first loss function, which depends on the MR measurement data and on the prior MR image, to generate an optimized MR image; and
c) applying a trained machine learning model (MLM) for image enhancement to the optimized MR image to generate an enhanced MR image, wherein the prior MR image of the respective iteration corresponds to the enhanced MR image of a preceding iteration unless the respective iteration corresponds to an initial iteration of the at least two iterations, and wherein the prior MR image of the initial iteration corresponds to a predefined initial image.

2. The computer implemented method according to claim 1, wherein the optimization of the first loss function is carried out under variation of a variable MR image, while the prior MR image is kept constant during the optimization.

3. The computer implemented method according to claim 2, wherein the first loss function comprises a regularization term, which depends on the prior MR image and the variable MR image.

4. The computer implemented method according to claim 2, wherein the first loss function comprises a data term, which depends on the MR measurement data and on encoded data, which is given by a predefined MR signal model matrix applied to the variable MR image.

5. The computer implemented method according to claim 4, wherein the data term quantifies a deviation between the MR measurement data and the encoded MR data.

6. The computer implemented method according to claim 4, wherein:
the MR measurement data corresponds to data measured according to at least two coil channels; and
the signal model matrix depends on respective predefined coil sensitivity maps for each of the at least two coil channels.

7. The computer implemented method according to claim 4, wherein:
a point spread function for a data acquisition process used for generating the MR measurement data is received; and
the signal model matrix depends on the point spread function.

8. The computer implemented method according to claim 4, wherein the signal model matrix depends on:
translation offsets describing a rigid motion of the imaged object; and/or
rotation angles describing the rigid motion of the imaged object.

9. The computer implemented method according to claim 4, wherein the signal model matrix depends on a deformation vector field describing a non-rigid deformation of the imaged object.

10. The computer implemented method according to claim 1, wherein the trained MLM is trained according to a training processes that comprises:
receiving training magnetic resonance (MR) data and a ground truth reconstructed MR image corresponding to the training MR data; and
performing at least two training iterations, wherein, for each training iteration of the at least two training iterations:
receiving a training prior MR image for the respective training iteration;
generating an optimized training MR image by optimizing a predefined second loss function, which depends on the training MR data and on the training prior MR image; and
generating an enhanced training MR image by applying the MLM to the optimized training MR image, wherein the training prior MR image of the respective training iteration corresponds to the enhanced training MR image of a preceding training iteration, unless the respective training iteration corresponds to an initial training iteration of the at least two training iterations, and the training prior MR image of the initial training iteration corresponds to a predefined initial training image;
evaluating a predefined third loss function depending on the enhanced training MR image of a final training iteration of the at least two training iterations and the ground truth reconstructed MR image; and
updating the MLM depending on a result of the evaluation of the third loss function.

11. The computer implemented method according to claim 10, wherein:
the optimization of the second loss function is carried out under variation of a variable MR image, while the training prior MR image is kept constant during the optimization; and
the second loss function comprises a data term, which depends on the training MR data and on further encoded data, which is given by a predefined further MR signal model matrix applied to the variable MR image.

12. The computer implemented method according to claim 11,
wherein the optimization of the first loss function is carried out under variation of a variable MR image, while the prior MR image is kept constant during the optimization, and the first loss function comprises a data term, which depends on the MR measurement data and on encoded data, which is given by a predefined MR signal model matrix applied to the variable MR image; and
wherein:
(a) a point spread function for a data acquisition process used for generating the MR measurement data is received, and the signal model matrix depends on the point spread function, the further MR signal model matrix being independent of the point spread function;
(b) the signal model matrix depends on: (i) translation offsets describing a rigid motion of the imaged object; and/or (ii) rotation angles describing the rigid motion of the imaged object, wherein the further MR signal model matrix is independent of the translation offsets and independent of the rotation angles; and/or
(c) the signal model matrix depends on a deformation vector field describing a non-rigid deformation of the imaged object, the further MR signal model matrix being independent of the deformation vector field.

13. A data processing apparatus comprising:
one or more processors; and
memory storing instructions that, when executed by the one or more processors, cause the apparatus to perform the method of to claim 1.

14. One or more non-transitory media storing instructions that, when executed by one or more processors, cause the one or more processors to perform the method of claim 1.

15. A computer implemented training method for training a machine learning model (MLM) for image enhancement for use in a computer implemented method, the method for training comprises:
receiving training magnetic resonance (MR) data and a ground truth reconstructed MR image corresponding to the training MR data; and
performing at least two training iterations, wherein, for each training iteration of the at least two training iterations:
receiving a training prior MR image for the respective training iteration;
generating an optimized training MR image by optimizing a predefined second loss function, which depends on the training MR data and on the training prior MR image; and
generating an enhanced training MR image by applying the MLM to the optimized training MR image, wherein the training prior MR image of the respective training iteration corresponds to the enhanced training MR image of a preceding training iteration, unless the respective training iteration corresponds to an initial training iteration of the at least two training iterations, and the training prior MR image of the initial training iteration corresponds to a predefined initial training image;
evaluating a predefined third loss function depending on the enhanced training MR image of a final training iteration of the at least two training iterations and the ground truth reconstructed MR image; and
updating the MLM depending on a result of the evaluation of the third loss function.

16. The computer implemented training method according to claim 15, wherein:
the optimization of the second loss function is carried out under variation of a variable MR image, while the training prior MR image is kept constant during the optimization; and
the second loss function comprises a data term, which depends on the training MR data and on further encoded data, which is given by a predefined further MR signal model matrix applied to the variable MR image.

17. A data processing apparatus comprising:
one or more processors; and
memory storing instructions that, when executed by the one or more processors, cause the apparatus to perform the method of claim 15.

18. One or more non-transitory media storing instructions that, when executed by one or more processors, cause the one or more processors to perform the method of claim 15.
